(19) United States
(12) Patent Application Publication
(10) Pub. No.: US 2013/0293987 A1
(43) Pub. Date: Nov. 7, 2013

(54) Quench Detection System for Superconducting Magnets

(71) Applicant: Brookhaven Science Associates, LLC, (US)

(72) Inventor: Piyush Nanubhai Joshi, Shoreham, NY (US)

(73) Assignee: Brookhaven Science Associates, LLC, Upton, NY (US)

(21) Appl. No.: 13/850,895

(22) Filed: Mar. 26, 2013

Related U.S. Application Data
(60) Provisional application No. 61/615,972, filed on Mar. 27, 2012.

(51) Int. Cl. G01R 33/12; H02H 7/00

(52) U.S. Cl. CPC G01R 33/1238; H02H 7/001
USPC 361/19; 324/71.6

(57) ABSTRACT

A quench detection device (or method) is provided that receives real-time information of concurrently monitored electrical characteristics of a high temperature superconducting (HTS) device, or any superconducting material, device, or system including low temperature superconductors, during operation. The quench detection device determines whether an electrical threshold is satisfied based on the received real-time information. The quench detection device detects a quench condition if the electrical threshold remains satisfied over a predetermined period of time or a predetermined successive number of times. If a quench detection is detected, the quench detection device sends a signal to terminate the operation of the HTS device.

### CROSS-REFERENCE TO A RELATED APPLICATION

This application claims the benefit under 35 U.S.C. §119(e) of U.S. Provisional Application No. 61/615,972 filed on Mar. 27, 2012, the content of which is incorporated herein in its entirety.

### STATEMENT OF GOVERNMENT LICENSE RIGHTS

The present invention was made with government support under contract number DE-ACO2-98CH10886 awarded by the U.S. Department of Energy. The United States government may have certain rights in this invention.

### FIELD OF THE INVENTION

The present disclosure relates to the field of High Temperature Superconducting materials or Superconductors (HTS), and more particularly, to an approach for detecting a quench condition in an HTS device and system.

### BACKGROUND

A superconductor is a material that is able to attain superconductivity or a superconductive state, a state in which its electrical resistance or resistive state drops to zero at or below a critical temperature. Superconductors have been used or proposed for use in numerous applications, including for magnets or magnetic elements that are used in particle accelerators (e.g., colliders and cyclotrons) and medical imaging.

Quench is a phenomenon during which the superconductor transits or changes from a superconductive state to a normal resistive state. During a quench, a superconductor begins to enter a normal resistive state, and thus may become damaged from resulting high voltage, temperature, and associated forces. As a consequence, it is important to detect impending quench in superconducting devices.

Quench detectors have been known for about 20 years for low temperature superconductors (LTS), materials that become superconducting at around liquid Helium temperature (or around 4 Kelvin). The quench phenomena in LTS is a fast spreading process, and thus generates large quench-related signals, with voltages on the order of tens of milli-Volts (m-Volts). Traditional operational amplifier and microprocessor-based circuits have been used to detect and process such signals.

There have been a number of advancements in the field of superconductors, particularly with the advent and use of high temperature superconductors (HTS), materials that become superconducting at a critical temperature above 30 Kelvin (−243.2° C.) or around liquid Nitrogen (or LN₂) temperature (77 Kelvin). The use of HTS in various devices places greater requirements on quench detection systems. Conventional quench detection systems, such as those used for LTS devices, are not fast, flexible or precise enough to detect quench in HTS devices.

Specifically, quench in HTS is a very local phenomenon meaning that it does not spread quickly to surrounding areas in the conductor. A primary difference between HTS quench and LTS quench is in the normal zone propagation (NZP) velocities, the propagation speed at which a normal zone (an area with a normal resistive state) spreads in the conductor. The NZP of an HTS is much slower, about 1-10 cm/sec as compared to the NZP of LTS, which is about 1-2 msec. As a consequence, an HTS quench detector must be able to respond significantly faster than conventional LTS quench detectors. The slow moving nature of quench in HTS also poses a further problem in HTS devices, such as HTS coils that store or are used to store large amounts of energy. If the current through the HTS device is not interrupted quickly and stored energy extracted fast enough during a quench condition, a very large amount of energy may be deposited in a very small normal zone resulting in damage to the conductor.

Furthermore, it is difficult to distinguish quench-related electrical signals quickly from other background signals in an HTS device, e.g., within 2-3 milliseconds in order to interrupt current and prevent burn-out of the conductor. The resistive voltage developed across a small normal zone in an HTS device can be very small-on the order of few 100 microvolts as opposed to a few 100 millivolts in case of a large normal zone in LTS coils. There also is background electrical noise and inductive voltages of higher magnitude that may further hamper detection of these very small quench-related electrical signals.

Accordingly, it would be desirable to provide a fast and reliable approach for detecting a quench condition in HTS devices and systems.

### SUMMARY

In accordance with an embodiment of the present disclosure, a quench detection device (or method) is provided that receives real-time information of concurrently monitored electrical characteristics of a high temperature superconducting (HTS) device, or any superconducting material, device, or system including low temperature superconductors, in operation. The quench detection device determines whether an electrical threshold is satisfied based on the received real-time information. The quench detection device detects a quench condition if the electrical threshold remains satisfied over a predetermined period of time or a predetermined successive number of times. If the quench condition is detected, the quench detection device sends a signal to terminate the operation of the HTS device.

In accordance with a further embodiment of the present disclosure, a quench detection device (or method) is provided that receives real-time information of concurrently monitored electrical characteristics of a high temperature superconducting (HTS) device during operation. The quench detection device discriminates between quench related electrical signals and non-quench related electrical signals observed from the received real-time information to determine a quench condition in the HTS device. If the quench condition is detected, the quench detection device sends a signal to terminate the operation of the HTS device.

### BRIEF DESCRIPTION OF THE DRAWINGS

The description of the various exemplary embodiments, is explained in conjunction with the appended drawings, in which:

FIG. 1 is a block diagram of an exemplary system environment for implementing quench detection for High Temperature Superconducting (HTS) devices in accordance with one disclosed embodiment.

FIG. 2A is a block diagram of an exemplary system environment for implementing quench detection for HTS devices in accordance with a further disclosed embodiment.

FIG. 2B is a block diagram of an exemplary system environment using 14-channel sampling for implementing quench detection for HTS devices in accordance with a disclosed embodiment.

FIG. 3A shows an exemplary system environment for implementing quench detection for HTS devices in accordance with an additional disclosed embodiment.

FIG. 3B shows an exemplary system environment using 14-channel sampling for implementing quench detection for HTS devices in accordance with an additional disclosed embodiment.

FIG. 4 shows an exemplary insulated-gate bipolar transistor (IGBT) switch.

FIG. 5 shows an exemplary HTS test coil.

FIG. 6 shows an exemplary HTS coil assembly.

FIG. 7A is a screen shot of an exemplary Host Human Machine Interface (HMI) Program used to display one or more operating characteristics of an HTS device under test.

FIG. 7B is a screen shot of an exemplary Host Human Machine Interface (HMI) Program used to display one or more operating characteristics of an HTS device under test for a 14-channel quench protection system (QPS).

FIG. 8 is a screen shot of LabVIEW Plots showing a quench condition of an HTS device under test.

FIG. 9 includes exemplary graphs of voltage versus current characteristics based on experimental results of an HTS device under test.

FIG. 10 is a flow diagram of an exemplary process to detect a quench condition in an HTS device in accordance with a disclosed embodiment.

FIG. 11 is a flow diagram of an exemplary process to detect a quench condition in an HTS device in accordance with a further disclosed embodiment.

FIG. 12 is a flow diagram of an exemplary process by which a potential quench condition violation is determined during a current ramping phase (or operation) in accordance with a disclosed embodiment.

FIG. 13 is a flow diagram of an exemplary process by which a potential quench condition violation is determined after a current ramping phase (or operation) or reaching a steady-state current phase (or operation) in accordance with a disclosed embodiment.

### DETAILED DESCRIPTION

In accordance with various disclosed embodiments, there is provided a method, device, and system to detect quench in a High Temperature Superconducting (HTS) device. As will be discussed in detail below with reference to the Figures, the disclosed method, device, and system can identify a presence of electrical signals in the HTS device during operation and implement real-time data filtering of these identified signals to detect fora presence (or absence) of quench in the HTS device. Although the various disclosed embodiments are described with reference to an HTS device, the quench detection described in this disclosure can be applied to detect quench in any superconducting material, device or system, including those made from Low Temperature Superconductors (LTS).

### A. System Environment

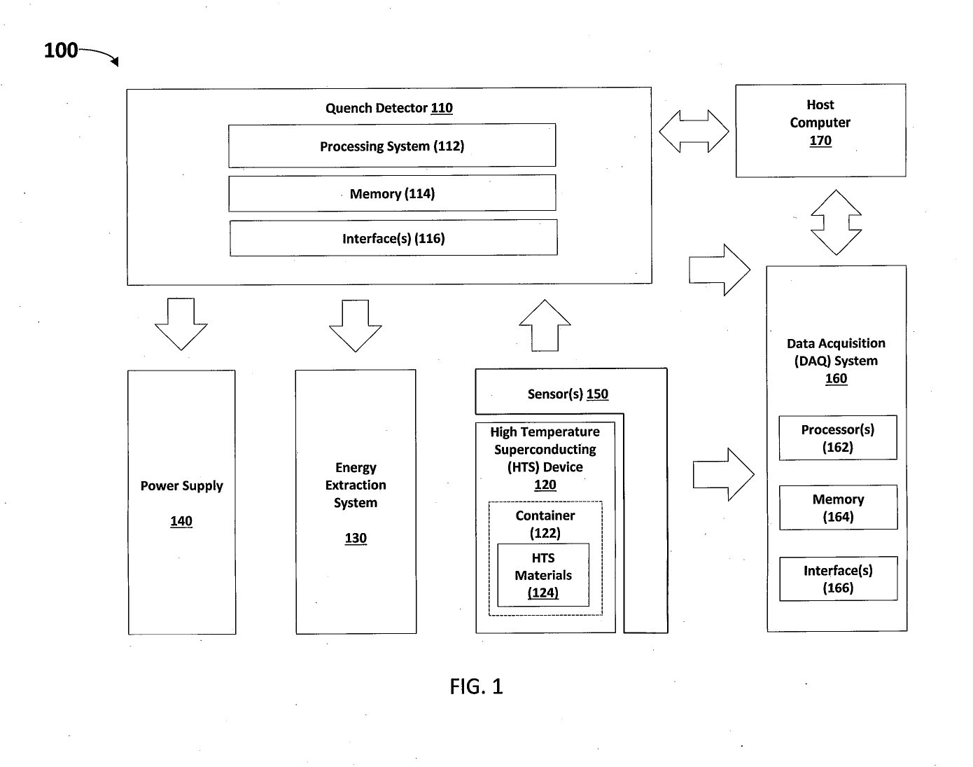

FIG. 1 illustrates a block diagram of an exemplary system environment 100 for implementing quench detection for an HTS device. As shown in FIG. 1, the system environment 100 includes an HTS device 120, a quench detector 110 for detecting a quench condition in the HTS device, an energy extraction system 130 for extracting (or dampening) energy from the HTS device, a power supply 140 for supplying power to the HTS device and any other components of the system environment 100, a plurality of sensors 150 for monitoring electrical and other characteristics of the HTS device, a data acquisition system 160 for collecting, storing, and processing monitored and other information about the HTS device, and a host computer 170 for providing a user interface to manage various processes including setting process parameters, view or display collected and processed data.

The HTS device 120 includes an HTS material 124 maintained in a container 122. The container 122 may be a vacuum container, such as a Dewar, or other suitable containment system for holding an HTS material 124 immersed in a coolant (e.g., liquid Nitrogen) for controlling a temperature of the HTS material. The HTS material 124 is a material that has a superconducting transition temperature (T_{c}) above 30 K (−243.2° C.) or around a temperature of Liquid Nitrogen (77 Kelvin). Some examples of HTS materials include but are not limited to: copper oxide superconductors such as Bismuth strontium calcium copper oxide (BSCCO), Yttrium barium copper oxide (YBCO) and rare-earth-barium-copper-oxide (RE-BCO); iron-oxide superconductors; and other rare-earth based HTS conductors made from Samarium or Gadolinium.

The HTS material 124 may be formed into components used in various types of devices and systems, such as magnets, solenoids, electrodes, transmission cables, particle accelerators, e.g., particle colliders, cyclotrons, synchrotrons or synchrocyclotrons, medical imaging instruments like MRI, HTS motors and generators, and superconducting magnetic energy storage (SMES) systems. For example, the HTS material 124 may take the form of a wire or tape which can be formed into other shapes or forms, such as a coil or cable. In an exemplary embodiment described below, second generation (2G) HTS tape manufactured by Super Power Inc. (Schenectady, N.Y.) can be used to form small HTS pancake coils.

An energy extraction system 130 extracts (or dampens) energy stored in the HTS device 120. The energy extraction system 130 can include a resistor(s), such as a dump resistor, which is connected to the HTS device across a switch or other connection mechanism. The energy extraction system 130 can be turned ON and OFF by a switch or other connection mechanism. The energy extraction system 130 extracts (or dampens) stored energy from the HTS device upon a desired condition, such as in response to a detection of a quench condition by quench detector 110.

The Data Acquisition (DAQ) system 160 includes processor(s) 162, memory 164 and interface(s) 166 for conducting communications or transmission with other components or devices. The DAQ system 160 collects, stores and processes monitored and other information about the HTS device. This information includes real-time information of electrical characteristics of the HTS device, detection (or non-detection) of signals from the quench detector 110, and other operational information from components of system environment 100.

The host computer 170 may include processor(s), internal and external memory for storing computer programs and other data, one or more input devices, one or more output devices, communication interface(s) and bus(es) for providing interconnectivity between the computer components and other devices and systems. The host computer 170 can implement various programs, including those to provide a human machine interface (HMI) to enable a user to control or program the quench detector 110 or other components of the system environment 100. The host computer 170 can also implement programs to enable a user to set quench detection criteria, and to set and control data acquisition of one or more monitored characteristics of an HTS device during operation. The host computer 170 can also implement programs to allow a user to view or display one or more characteristics of the HTS device, e.g., current, voltage, and quench detection, in real-time or archived monitored results of prior performance characteristics of the HTS device. For example, the host computer 170 may include a program, such as National Instrument's LabVIEW program.

As further shown in FIG. 1, the quench detector 110 includes a processing system 112, memory 114 and interface(s) 116. The memory 114 can be a non-transitory computer-readable storage medium used to store executable instructions, computer program(s), or other data including but not limited to quench parameters defining a quench condition. These parameters can include a voltage threshold, counter threshold and time threshold. The memory 114 may include a read-only memory (ROM), random access memory (RAM), programmable read-only memory (PROM), erasable programmable read-only memory (EPROM), a smart card, a subscriber identity module (SIM), or any other medium from which a computing device can read executable instructions or a computer program. The term “computer program” is intended to encompass an executable program that exists permanently or temporarily on any computer-readable storage medium as described above.

The computer program also includes an algorithm that includes executable instructions or instruction code stored in the memory 114 that are executable by the processing system 112. The algorithm may be facilitated by one or more programs also stored on the memory 114 or on another computer system.

The interface(s) 116 includes transmit and receive circuitry (or components) for communicating or transmitting signals between other components or devices, such as those in system environment 100. The communications can include receipt of information of a plurality of monitored electrical characteristics of the HTS device, transmission of control signals and information, including signals to terminate operation of the HTS device, signals to implement energy extraction (or dampening) from the HTS device, signals to turn on or off the power supply, information relating to detection (or non-detection) of a quench condition in the HTS device, receipt of a computer program or programming instructions or updates, or receipt of detection configuration information (including but not limited to quench condition parameters).

The processing system 112 implements various processes and logic flows to implement a quench detection environment or system. The processing system 112 can be one or more programmable processors that can execute one or more computer programs to perform functions by operating on input data and generating output. The processing system 112 can also take the form of special purpose logic circuitry, e.g., an FPGA (field programmable gate array) or an ASIC (application specific integrated circuit) or a CPLD (Complex Programmable Logic Device), to implement processes and logic flows, or a combination thereof e.g., processor(s) and/or programmable logic circuitry.

In accordance with a disclosed embodiment, the processing system 112 is configured to receive real-time information of concurrently monitored electrical characteristics of a high temperature superconducting (HTS) device in operation, determine whether an electrical threshold is satisfied based on the received real-time information, and detect a quench condition if the electrical threshold remains satisfied over a predetermined period of time or a predetermined successive number of times. Upon detection, the processing system controls termination of an operation of the HTS device.

The electrical threshold can be a voltage threshold. In this case, the processing system can be configured to compare a voltage difference to the voltage threshold in order to determine whether an electrical threshold is satisfied. The voltage difference can be a difference between two voltage measurements obtained based on the monitored (or sampled) electrical characteristics of the HTS device at an instance in time. The voltage measurement can be of an inductive voltage or a resistive voltage of the HTS device or a portion(s) thereof.

The HTS device can be an HTS coil(s) having a plurality of coil portions. The processing system 112 ascertains a voltage across each coil portion or a selected coil portion(s) from the received real-time information, and compares a voltage difference between voltages across different or separate coil portions e.g., a first portion and a second portion, an upper portion and a lower portion, to the voltage threshold in order to determine whether the voltage threshold is satisfied (or not). In addition, when the HTS device is undergoing a current ramping phase (or operation), the processing system 112 can be configured to determine whether the voltage threshold is satisfied by implementing the following process: determining a voltage difference between (i) an inductive voltage (L·di/dt) computed from a ramping current determined from the received real-time information and (ii) a voltage across the HTS device determined from the received real-time information; and comparing the voltage difference to the voltage threshold in order to determine whether the voltage threshold is satisfied.

Accordingly, the processing system 112 can select and implement different quench detection processes depending, for example, on an operational phase of the HTS device, e.g., a current ramping phase and a steady-state current phase. The processing system 112 can select particular monitored electrical characteristics from a plurality of monitored electrical characteristics (for which real-time information is received) according to an operational phase(s) of the HTS device. The processing system 112 can then determine whether an electrical threshold is satisfied based on the received real-time information of the selected monitored electrical characteristics.

In various exemplary implementations, a voltage threshold can be between 0.5 to 5 m-Volts. The processing system 112 can be configured to detect a quench condition and control interruption of current to the HTS device, for example, within 1 milli-second (m-sec) to 5 m-sec from an occurrence of a quench in the HTS device. The current can be interrupted in 20 micro-sec (μ-sec) after quench detection.

In accordance with another disclosed embodiment, the processing system 112 is configured to receive real-time information of a plurality of concurrently monitored electrical characteristics of a high temperature superconducting (HTS) device in operation. The processing system 112 can then discriminate between quench- and non-quench-related electrical signals observed from the received real-time information to determine a quench condition in the HTS device.

For example, the processing system 112 can be configured further to obtain a plurality of voltage measurements of the HTS device based on the received real-time information. The processing system 112 detects a presence of electrical signals in the HTS device from voltage subtraction of two voltage measurements from the plurality of voltage measurements. The processing system 112 filters out instances in which the detected electrical signal is related to quench to determine a quench condition in the HTS device. The processing system 112 can count a number of successive times the subtracted voltage exceeds, or is greater than or equal to a voltage threshold over time, and determine a quench condition if the counted number of successive times is greater than or equal to a counter threshold.

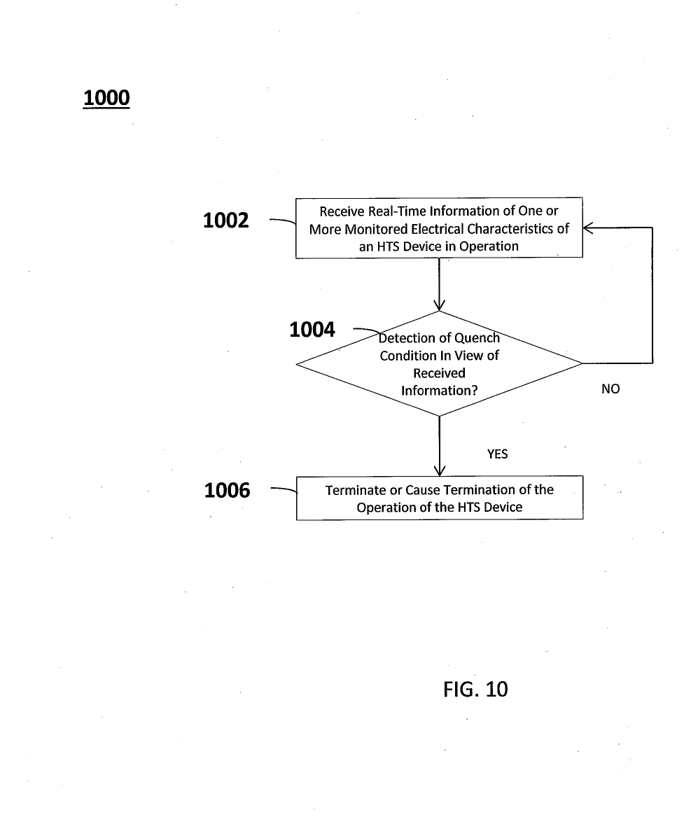

The specifications provide a few exemplary implementations of the various methods and processes implementable by the quench detector 120. The processing system 112 of the quench detector 120 may implement these and other processes, such as those described below with reference to FIGS. 10 through 13.

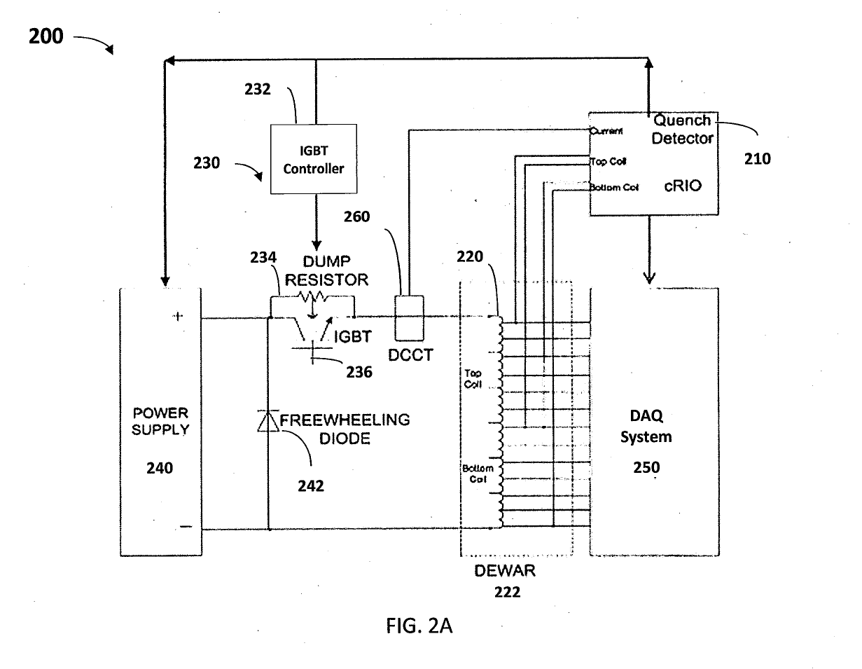

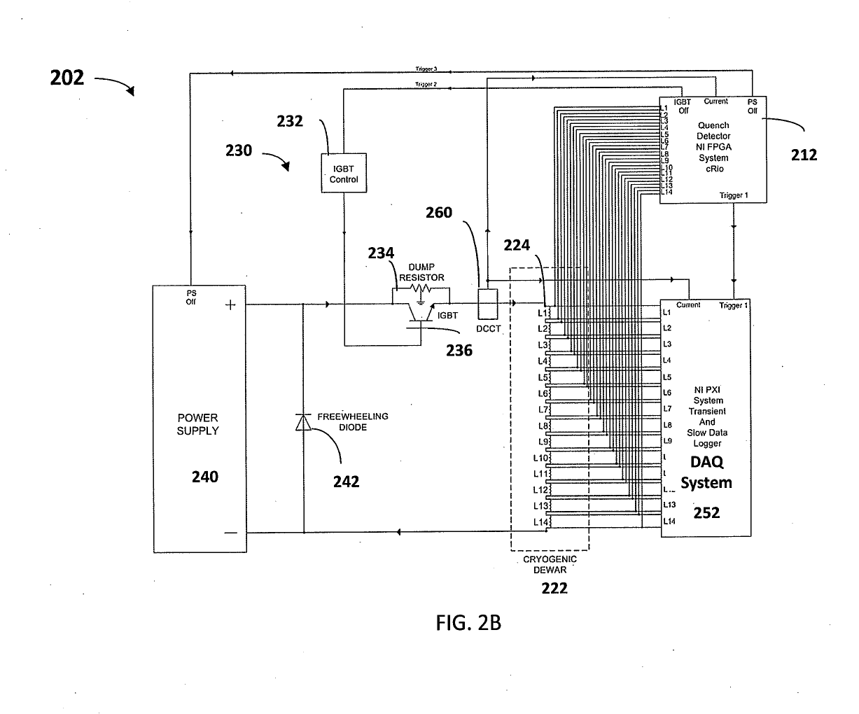

FIG. 2A illustrates a block diagram of an exemplary system environment 200 for implementing quench detection for HTS devices in accordance with a further disclosed embodiment. The system environment 200 includes an HTS device 220 having a plurality of coil portions (or sections) arranged in a Dewar 222 for holding a coolant, such as liquid Nitrogen to facilitate cooling of the HTS device. In this example, the HTS device 220 includes a top coil portion and a bottom coil portion. The system environment 200 also includes a quench detector 210 for detecting a quench condition in the HTS device 220 and an energy extraction system 230 for extracting (or dampening) stored energy from the HTS device 220. As further shown in FIG. 2A, the system environment 200 includes a power supply 240 for supplying power to the HTS device 220 or other components, a DC current transformer (DCCT) 220 for measuring a current, voltage taps for collection of voltage measurements from different portions of the HTS device e.g., voltage taps for a top coil and a bottom coil, and a data acquisition system (DAQ) 250 for collecting, storing and processing data concerning an operation of the HTS device 220. The various components of FIG. 2A, such as the HTS device 220, quench detector 210, power supply 240 and DAQ 250 may be similar to the corresponding components described above with reference to FIG. 1.

As further shown in FIG. 2A, the energy extraction system 230 includes an insulated-gate bipolar transistor (IGBT) controller 232, a dump resistor 234 and an IGBT switch 236. The energy extraction system 230 is controlled via controller 232 to selectively switch ON-OFF the switch 236. In response to a quench detection, the controller 232 is configured to turn OFF switch 236 which then allows energy extraction (or dampening) from the HTS device 220 to the dump resistor 234. Further, in FIG. 2A, a freewheeling diode 242 is connected in parallel to the power supply 240 and is used to provide a current flow path from the coil to the dump resistor. In this example, a switch is turned OFF to terminate operation of the HTS device. It should however be understood that the operation and termination of the HTS can be controlled in various ways, such as turning ON a switch to terminate operation of the HTS device or turning OFF a switch to allow operation of the HTS device.

The quench detector 210 may include components, such as a processing system, memory, and interface(s), and implement methods and processes for quench detection, similar to or the same as that described above for the quench detector 120 in FIG. 1.

In accordance with a further exemplary implementation, the quench detection system can be configured with the following specifications: a quench detection response time of less than 5 m-sec; a quench detection voltage threshold (overall) of 1 m-Volt; a coil current interruption time after quench detection of about 100 microsecond; and voltage measuring electronics having channel-to-channel and channel-to-ground isolation of at least 300 Volts and up to 1000 Volts. The voltage threshold can be determined or set based on any number of factors, including those related to the nature of the superconducting materials such as a thickness of the cladding, e.g., a copper cladding, a length of the superconducting material or wire, and an operational temperature of the superconducting device.

In another exemplary implementation, the quench detector can be a 72-channel quench monitoring system. The energy extraction system can also be configured to be capable of extracting up to 2.5 Mega-Joules (M-J), or more, depending on the respective sizes of the dump resistor and superconducting coil. The DAQ system can be configured to implement 96-channel simultaneous sampling with high voltage channel-to-channel and channel-to-ground isolation of at least 500 Volts and up to 1000 Volts. The DAQ system and a quench protection system (QPS) system can be implemented to work in coordination with a persistence/by-pass switch and last stage of converter. In this example, the processing system is a FPGA-based system to implement fast computing and action.

FIG. 2B depicts another exemplary system environment 202 similar to that shown in FIG. 2A, except that a 14-channel simultaneous sampling is used to implement quench detection. As shown in FIG. 2B, the system environment 202 contains similar components as system environment 202, such as those described above with reference to FIG. 2A. In this disclosed embodiment, the system environment 202 employs a quench detector 212 and a DAQ system 252 that are configured to receive and process real-time information from 14-channels of monitored electrical characteristics of an HTS device 224. For example, the voltage is monitored across 14 separate coil portions of an HTS device 224.

There are additional challenges when implementing a multi-channel quench protection system. As a consequence, some additional measures are taken. For example, the electronics are protected against high (L·di/dt) voltage as the number of coil pairs and inductance increases. The data logger is designed with channel-to-channel and channel-to-ground isolation of at least 1000 Volts. The current interrupter IGBT switch becomes a complex assembly of series and parallel devices. The use of a bigger dump resistor may develop higher voltage across the IGBT and QPS electronics, and thus act as a limiting factor in determining a rate of energy extraction. Two or more backplanes also are synchronized. Simultaneous sampling for A/D is kept track. Coil pairs are selected with matching inductance and surrounding magnetic field.

### EXAMPLE

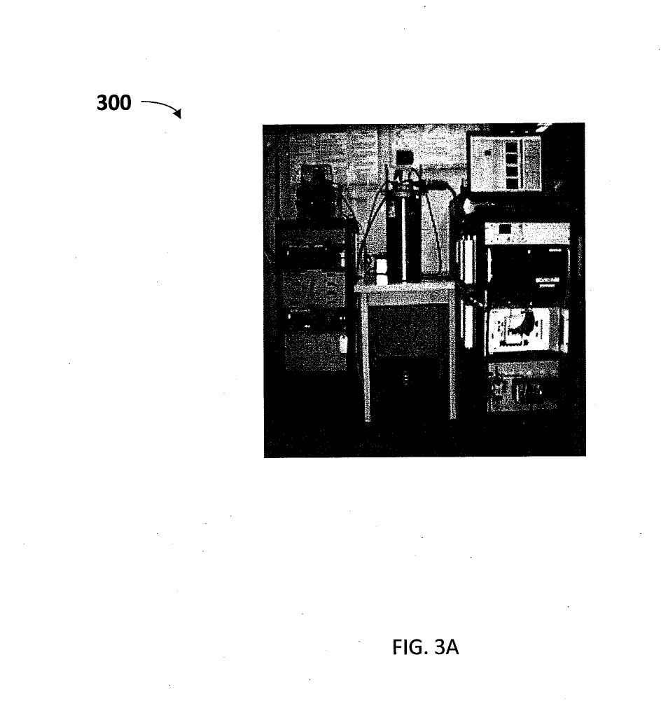

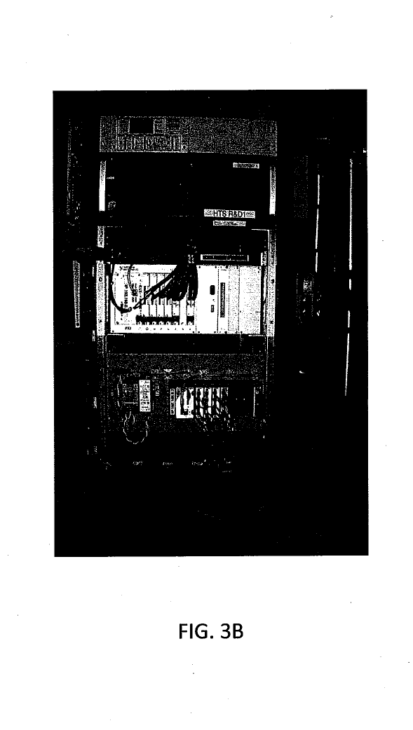

An exemplary quench detection environment or system was developed and tested using various exemplary components, configurations, and system specifications, and is described in greater detail below with reference to FIGS. 3 through 9. The performance of this system was evaluated by studying quench and voltage tap data of small pancake coils made from second generation (2G) HTS tapes from Super Power Inc. As discussed in greater detail below, the exemplary system confirms the usefulness of FPGA-based systems in protecting HTS coils. The quench detection in HTS demands a response time of 2 to 3 m-sec and quench threshold as low as 1 mV. Experiments using test coils immersed in liquid Nitrogen (LN₂) showed that the exemplary quench detection approach described in the present disclosure is able to satisfy these criteria and can provide a compact and easy to operate tool for the HTS R&D.

1. Exemplary System Hardware

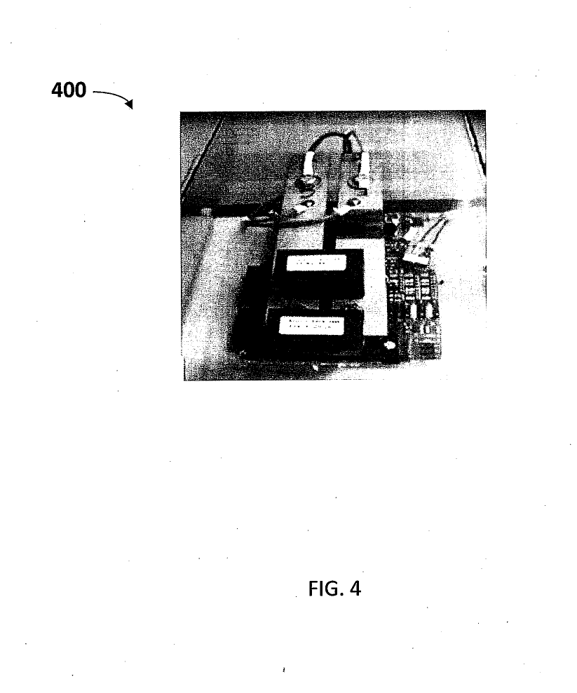

An overview of the exemplary system is shown in FIG. 3A. As shown in this Figure, there are two real-time controller platforms from National Instruments (NI) to implement quench detection and data acquisition, an energy extraction Insulated Gate Bipolar Transistor (IGBT) switch manufactured by Infineon Inc. (shown in greater detail in FIG. 4), a dump resistor, and an industrial PC. The system is configured to perform functions as follows: (1) Quench detection, (2) Slow data logging, (3) Transient data logging during an interval just before and after quench, (4) Coil current ramp profile control, and (5) Energy extraction.

The quench detection platform in this exemplary system uses a Compact RIO or CRIO backplane manufactured by National Instruments (NI). A CRIO is a real-time embedded industrial controller that is a combination of a real-time controller, reconfigurable IO Modules (RIO), Field Programmable Gate Array (FPGA) module, and an Ethernet expansion chassis. The exemplary system employs an exemplary CRIO configuration that is powered by a reconfigurable Field Programmable Gate Array (FPGA) technology, a real-time controller, a Data Acquisition (DAQ) module with 4 channels, 50 KS/s simultaneous sampling, 16-bit Analog-to-Digital (A/D) converter and a 16-channel fast digital Input/Output (JO) module.

The transient and slow data logger platform in this exemplary system includes: a National Instruments (NI) PCI eXtensions for Instrumentation (PXI) chassis; a real-time controller; four PXI DAQ modules each with 8 channels; a 16-bit, 50KS/s simultaneous sampling A/D converter and two PXI DAQ modules each with 16 channels; and a 250KS/s, multiplexed, 16-bit A/D converter. The PXI chassis may also house four NI SCXI-1125 isolation amplifier modules or it may employ external voltage clamps for voltage isolation and suppression. The four NI SCXI-1125 isolation amplifier modules can provide 300 Volt channel-to-channel isolation and 300 Volt channel-to-ground isolation. The external voltage clamps for voltage isolation and suppression can provide up to 1000 Volt channel-to-channel isolation and up to 1000 Volt channel-to-ground isolation. Both of the above targets are monitored and interfaced via local network connection to an industrial PC.

PXI is a rugged PC-based platform that offers a solution for measurement and automation systems. PXI combines the Peripheral Component Interconnect (PCI) electrical bus with the rugged, modular Eurocard mechanical packaging of Compact PCI and adds specialized synchronization buses and key software features. PXI also adds mechanical, electrical, and software features that define complete systems for test and measurement, data acquisition, and manufacturing applications.

In the operation of this exemplary system, energy extraction during quench is implemented by simultaneously turning off the IGBT switch (shown in FIG. 4) and the power supply to divert freewheeling current through the dump resistor, and thus dissipating coil-stored energy into the dump resistor. The value of a dump resistor R can be selected based upon total circuit induction and the rate at which energy needs to be extracted. If the copper to-superconductor ratio of the wire is large and quench resistance is small relative to the dump resistor, the value of the dump resistor can be computed approximately with the following equation:

I²t_{d}+I²L/2R=1500A² (1)

where I is initial quench current (k-A); L is the total circuit induction (H), A is the copper cross sectional area (cm) that stabilizes the superconducting wire, and R is in ohms. The dump resistor can be grounded at center to limit the peak voltage to ground.

An overview of another exemplary system is shown in FIG. 3B, which employs 14-channel simultaneous sampling of electrical characteristics of an HTS device under test.

2. Software

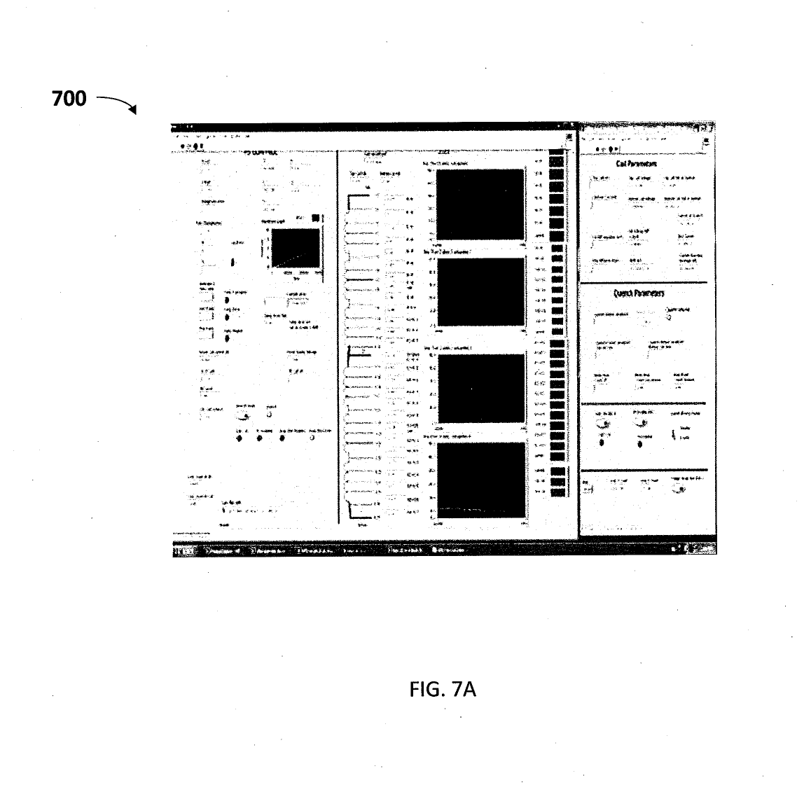

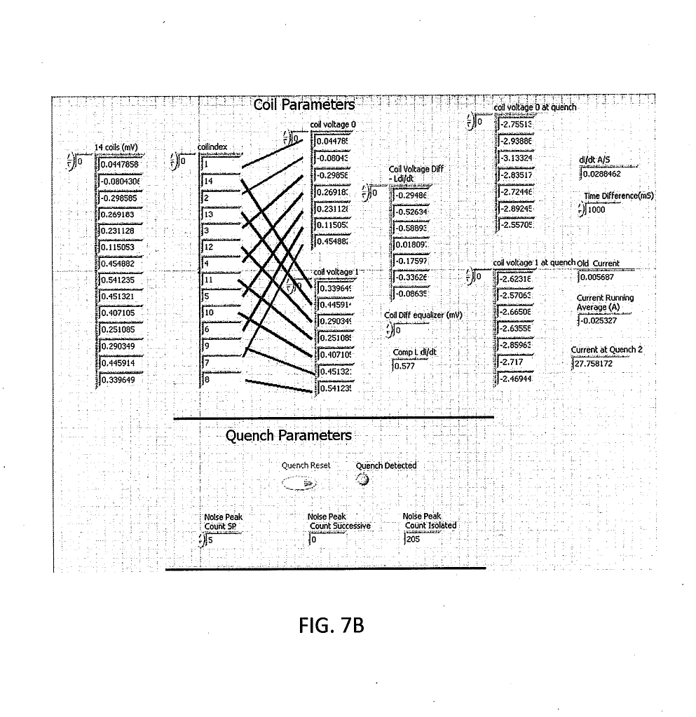

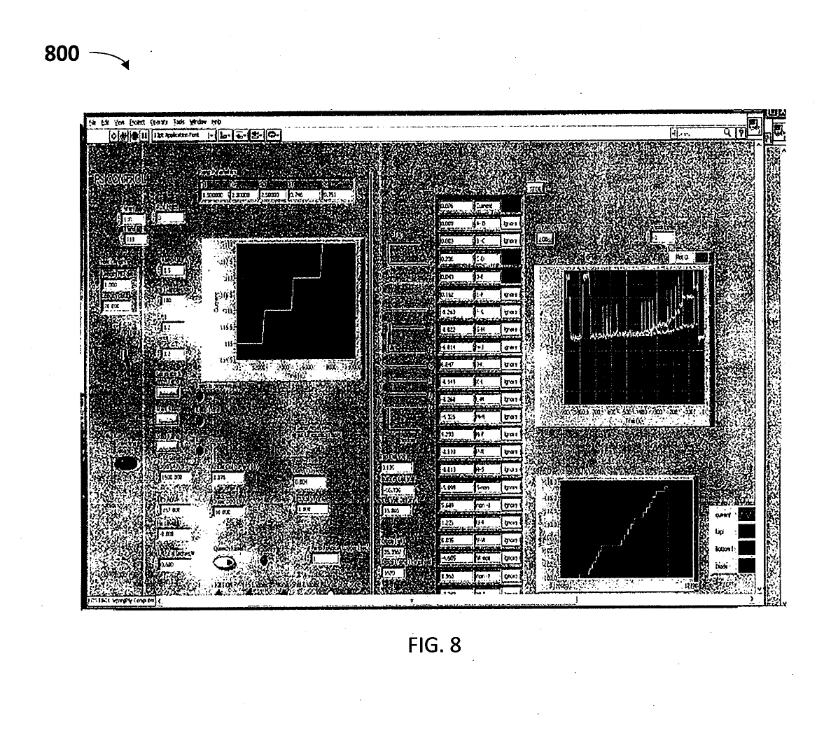

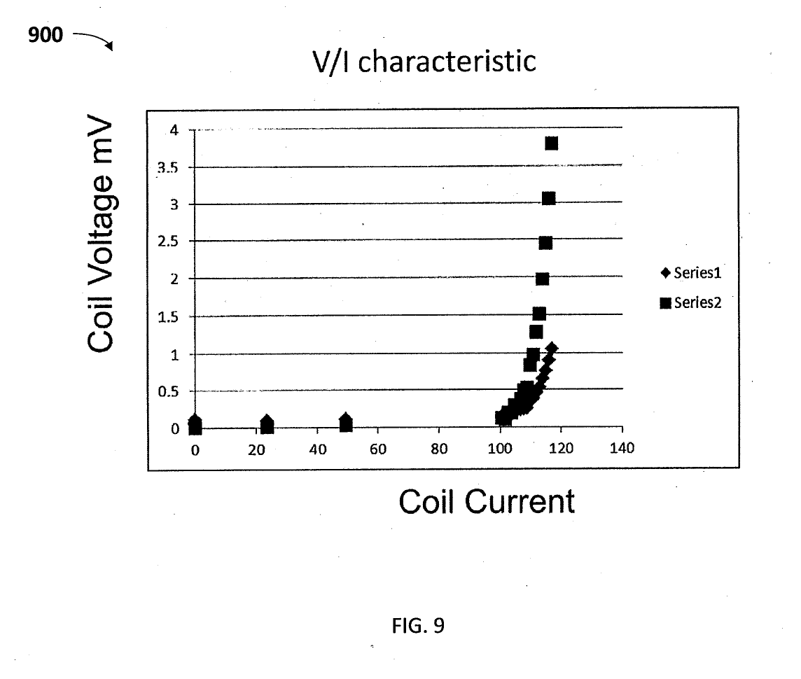

In the exemplary quench detection system, the software was developed using a graphical design language LabVIEW from National Instruments (NI). There are three separate LabVIEW VIs (Virtual Instrument) modules: (1) FPGA code for quench detection running on a CRIO target, (2) Real time data logging and monitoring code running on a PXI target, and (3) Host code running on an industrial PC to provide HMI (Human Machine Interface) such as shown in FIG. 7A. An exemplary screenshot of LabVIEW graph plots showing quench in an HTS device under test is shown in FIG. 8. FIG. 9 further illustrates an exemplary graph of voltage versus current characteristics based on experimental results of an HTS device under test. A screenshot is also shown in FIG. 7B, which displays coil parameters and quench parameters for an exemplary 14-channel voltage sampling quench detection system.

The FPGA code for quench detection implements two exemplary detection schemes. In the first scheme, the voltage across one half of the HTS coil under test is compared to a voltage across the other half of the coil. If the voltage difference exceeds a preset (or predetermined) voltage threshold, a quench is detected and a detection signal is transmitted via digital output to turn off the IGBT switch and to turn off the power supply. As discussed above, by turning off the IGBT switch, energy can be extracted through the dump resistor.

In the second scheme, a process is implemented to detect for quench during a current ramping phase. The instantaneous ramp rate is computed from a monitored coil current signal. From the known value of the coil inductance (L), a voltage L*di/dt across the coil is computed. This computed value is then compared with a measured coil voltage, such as through voltage taps. If the voltage difference exceeds a preset (or predetermined) voltage threshold, a quench is detected and a detection signal is transmitted to turn off the IGBT switch and to turn off the power supply (or the supply of power).

In both exemplary schemes, it is desirable to perform accurate and fast measurement of coil voltage(s) particularly among background noise, e.g., power line noise and stray noise spikes. A conventional method of filtering using a 4 Hz low-pass filter built in a DAQ module increases a response time by a few 100 m-sec; however, this may be insufficient in the case of quench detection in an HTS device. Accordingly, to provide for a faster and more accurate measurement and detection scheme, a quench detection approach is provided that implements real-time discrete filtering by using a processing system or the like with a fast loop time, such as for example an FPGA with a loop time of 50 μsec to 100 μsec.

In an exemplary operational example, every time a sample of coil voltage exceeds a pre-set quench threshold, a voltage threshold generally between 0.5 m-V to 5 m-V, a counter is updated. If the value of following coil voltage sample falls below the voltage threshold, the counter is reset to zero. Otherwise, if the value of the following coil voltage sample exceeds the voltage threshold, the counter is incremented by one. The next sample is taken and this process of checking to reset or increment the counter is performed again. At any time, if the counter value exceeds a counter threshold, for example, a pre-set number generally between 5 and 10 successive instances in which the sample exceeded the quench threshold, then quench is detected and a quench detection signal is issued or transmitted accordingly. Noise due to power supply or burst of stray EMI is thus effectively reduced or eliminated giving effective filter response time, for example, of 250 μ-sec to 500 μ-sec.

In this exemplary system, the real-time code running on the PXI target is configured to log and display all voltage tap values. Since this is slow data, a more conventional filtering method of averaging over a large number of power line cycles is used. The pre- and post-quench data of voltage taps values are recorded raw so that transient data is not lost and appropriate filtering can be applied offline. PS control and reference signal for current ramp is also generated by this program.

3. Test Coils

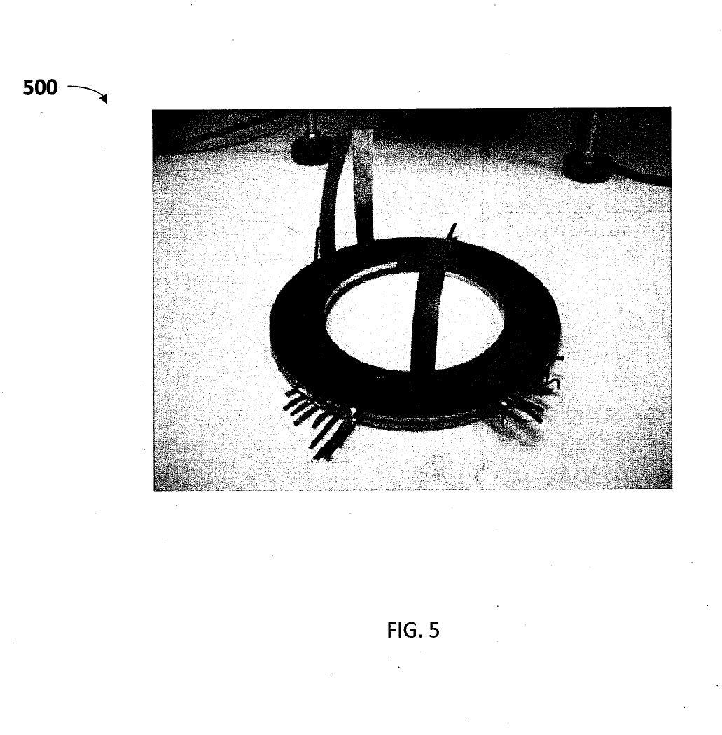

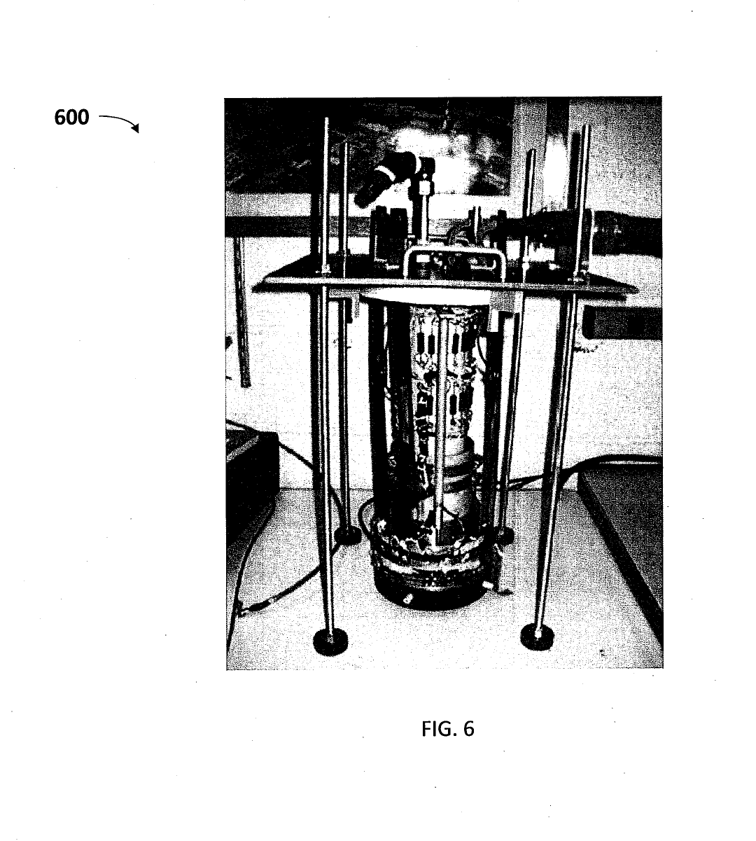

To test the exemplary system, small pancake coils (shown in FIG. 5) with an outer diameter of 160 mm and inner diameter of 100 mm were wound using second generation (2G), 4 mm wide HTS tape from Super Power Inc. The total length of the tape is about 100 m with a voltage tap inserted at every 10 m. Stainless steel tape of 0.025 mm thickness is co-wound to serve as turn-to-turn insulation. Two such pancakes are then clamped between Micarta flanges. The coil assembly as shown in FIG. 6 is then immersed in a liquid nitrogen Dewar (as shown in FIG. 3A).

Manufacturer provided critical current value defined in terms of microvolt/cm for this conductor is 1 μ-volt/cm for a short sample and self-field. For magnet use and therefore for test purposes, a more stringent criteria was used in defining critical current at 0.1 μ-V/cm. This resulted in a quench threshold set point, for example, of 1 m-V/coil because, each coil has 100 m of conductor.

4. Evaluation

To evaluate the performance of the exemplary system, the test coils were ramped in liquid Nitrogen (LN₂) at different ramp rates up to 45 Amps (A), at multiple times, each time lowering the quench threshold voltage starting from 10 m-V going down to 1 m-V. The coils could be ramped up and down at 1 m-V threshold; below that random trips started happening. After establishing a minimum threshold, the filter counter threshold value was lowered until a quench threshold of 1 m-V could be maintained. It was possible to lower the noise spike counter down to a 3 m-sec interval without triggering spurious trips.

### B. Exemplary Processes

Various exemplary processes implementable by a processing system or the like of a quench detector, e.g., 110 or 210 are described below with reference to FIGS. 10 through 13.

FIG. 10 is a flow diagram of an exemplary process 1000 implemented by a quench detector of a detection system to detect a quench condition or signal in an HTS device in accordance with a disclosed embodiment. The process begins at step 1002 with the quench detector receiving real-time information of one or more monitored electrical characteristics of the HTS device in operation. The received information of the monitored electrical characteristics may reflect or be used to determine a voltage measurement(s), e.g., an inductive voltage or resistive voltage, a current measurement(s), and/or other electrical related measurements associated with the HTS device or its operation.

At step 1004, the quench detector detects whether a quench condition exists (or not) in view of the received real-time information. For example, the quench detector identifies electrical signals, such as electrical voltage signals, from the real-time information (or sampling) of one or more electrical characteristics of the HTS device, and discriminates those signals related to quench from other electrical signals in order to detect a quench condition in the HTS device. The electrical signals related to quench may be ascertained through voltage subtraction, e.g., comparing voltages to ascertain a voltage difference. To implement such discrimination, the quench detector may implement real-time data filtering which may entail comparing measurements of the electrical signals to a threshold, identifying whether the threshold is satisfied or violated, and recognizing the signal as a quench-related signal if the threshold remains or continues to be satisfied or violated over a predetermined period of time, e.g., a time threshold or over a predetermined successive number of times, e.g., a counter threshold.

If a quench condition is not detected, the quench detector continues to receive real-time information (or samplings) of one or more electrical characteristics at step 1002 and to detect for quench at step 1004. If quench is detected, the quench detector terminates or causes termination of the operation of the HTS device. For example, the quench detector may transmit a control signal(s) (or trigger(s)) to turn off power such as provided by a power supply to the HTS device, to enable energy extraction (or dampening) of any energy stored in the HTS device, and/or to control or inform any other system components in view of the quench detection. For example, the control signal may trigger an alarm, e.g., audio and visual, locally such as at a host computer or remotely at a remote device to inform a user or personnel of a quench condition in the HTS device.

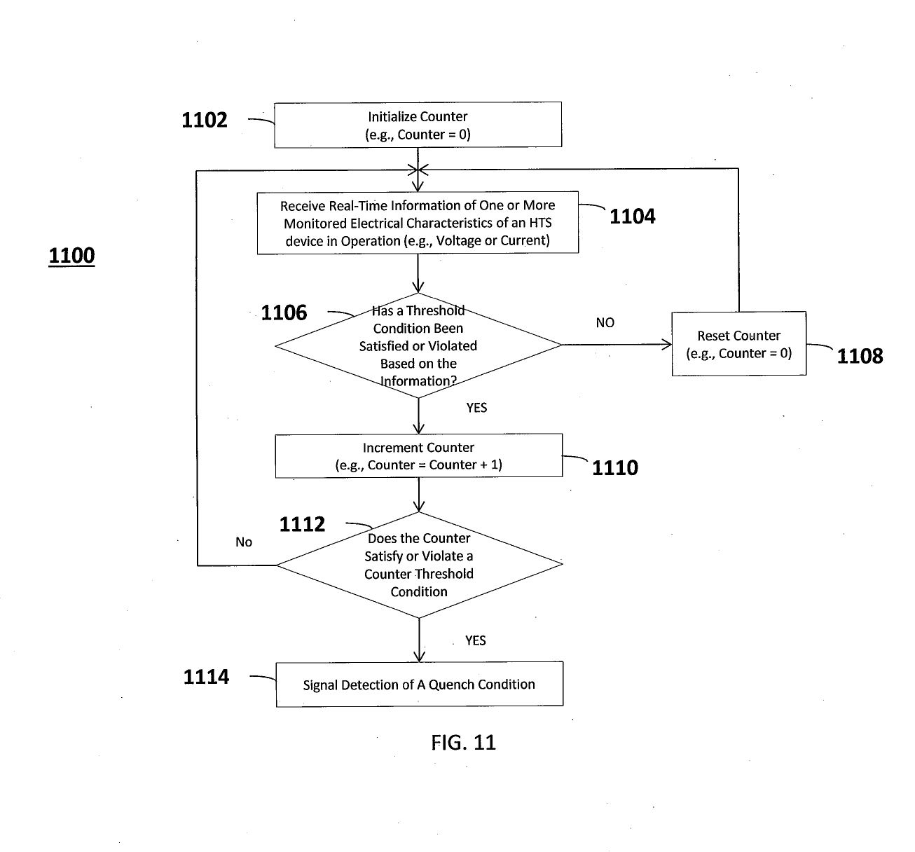

FIG. 11 is a flow diagram of an exemplary process 1100 implemented by a quench detector to detect a quench condition in an HTS device in accordance with a further disclosed embodiment. The process 1100 begins at step 1102 in which a counter is initialized, e.g., counter=0. At step 1104, the quench detector receives real-time information of one or more monitored electrical characteristics of the HTS device in operation. The received information of the monitored electrical characteristics may reflect or be used to determine a voltage measurement(s), e.g., an inductive voltage or resistive voltage, a current measurement(s), and/or other electrical related measurements associated with the HTS device or its operation.

At step 1106, the quench detector determines whether a threshold has been satisfied or violated based on the received real-time information. For example, the quench detector determines a measurement of an electrical signal based on the received real-time information and compares the measurement to an electrical threshold. In an exemplary embodiment, the electrical threshold can be a voltage threshold and the measurement can be of a voltage, such as a voltage difference between two voltage measurements taken from different portions of the HTS device and/or determined from other monitored electrical characteristics of the HTS device. If the voltage difference equals or exceeds the voltage threshold, then a threshold condition is satisfied. The voltage can, for example, be a resistive voltage or an inductive voltage.

If the threshold condition is not satisfied or violated, the quench detector proceeds to step 1108 in which the counter is reset, e.g., counter=0, and then returns to step 1104 to continue receiving real-time information. Otherwise, if the threshold condition is satisfied or violated, the process 1100 proceeds to step 1110 in which the counter is incremented, e.g., counter=counter+1. At step 1112, the quench detector determines whether the counter satisfies or violates a counter threshold condition. For example, a counter threshold condition is satisfied or violated if the counter is greater than or equal to a counter threshold. In this example, the counter is used to track a successive number of times that the electrical threshold condition is satisfied or violated.

If the counter threshold is not satisfied or violated, the process 1100 returns to step 1104 and continues to receive real-time information for further evaluation. Otherwise, if the counter threshold is satisfied or violated, the quench detector transmits a signal indicating detection of a quench condition at step 1114. For example, the quench detector may transmit a control signal(s) to turn off power such as provided by a power supply to the HTS device, to enable energy extraction (or dampening) of any energy stored in the HTS device, and/or to control or inform any other system components in view of the quench detection. For example, the control signal may trigger an alarm, e.g., audio and visual, locally such as at a host computer or remotely at a remote device to inform a user or personnel of a quench condition in the HTS device.

Although the above describes the use of a counter and counter threshold to implement data filtering, the quench detection approach of the present disclosure may employ other similar data filtering approaches, such sample averaging.

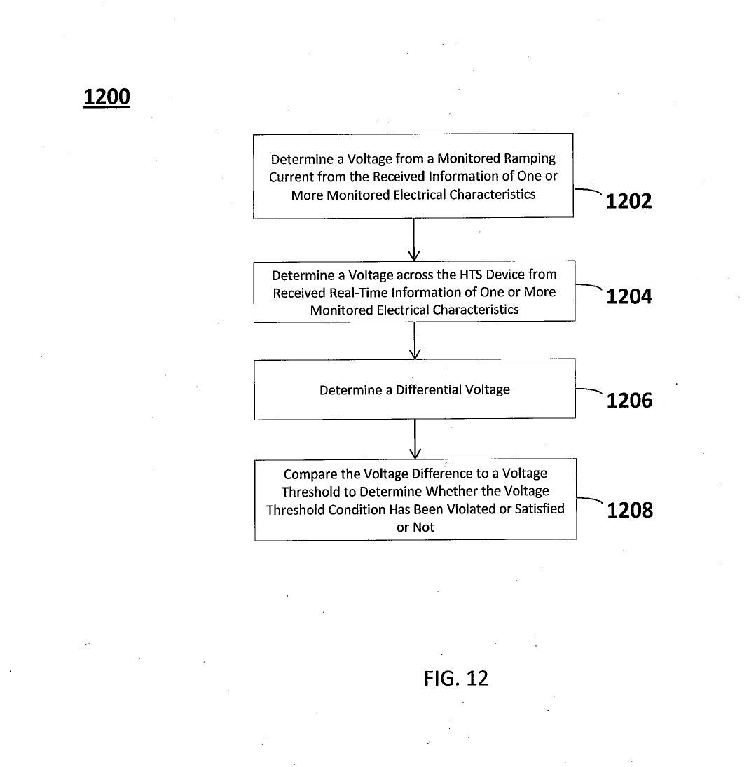

FIG. 12 is a flow diagram of an exemplary process 1200 by which a potential quench condition violation or signal is determined during a current ramping phase in accordance with a disclosed embodiment. The process 1200 begins at step 1202 in which the quench detector determines a voltage from a monitored ramping current based on received real-time information of one or more monitored electrical characteristics, such as a rate of current change (di/dt). From this information, an inductive voltage can be ascertained if the inductance (L) of the HTS device is known.

At step 1204, the quench detector determines a voltage across the HTS device from the received information of one or more monitored electrical characteristics. For example, the quench detector can measure a voltage across the HTS device using voltage taps or the like.

At step 1206, the quench detector determines a differential voltage between the voltage from step 1202 and the voltage from step 1204. For example, the quench detector can compute a difference between actual coil voltage and computed inductive voltage. The presence of a voltage difference depends on the existence and characteristics of electrical signals in the HTS device at an instance in time.

At step 1208, the quench detector compares the voltage difference to a voltage threshold to determine whether the voltage threshold condition has been violated or satisfied (or not). For example, a voltage threshold condition is violated or satisfied if the voltage difference exceeds or is greater than or equal to a voltage threshold.

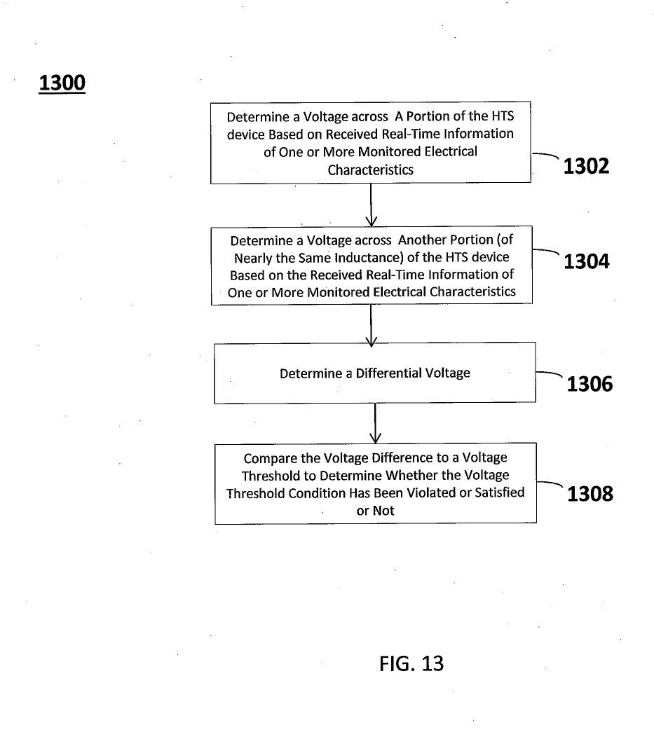

FIG. 13 is a flow diagram of an exemplary process 1300 by which a potential quench condition violation or signal is determined after a current ramping phase or reaching a steady-state current in accordance with a disclosed embodiment.

The process 1300 begins at step 1302 in which the quench detector determines a voltage across a portion of the HTS device from the real-time information of one or more electrical characteristics. For example, the HTS device, e.g., a coil, may have voltage taps arranged across a plurality of portions (or sections) of the HTS device so that a voltage across each or any portion of the HTS device can be ascertained.

At step 1304, the quench detector also determines a voltage across another portion (of the same or nearly the same inductance) of the HTS device from the received real-time information of one or more monitored electrical characteristics. As discussed above, this information may be ascertained from voltage taps arranged across a plurality of portions (or sections) of the HTS device.

At step 1306, the quench detector determines a differential voltage between the voltage across one portion of the HTS device from step 1302 and the voltage across another portion of the HTS device from step 1304. The existence of a voltage difference reflects the presence of electrical signals in the HTS device at an instance in time.

At step 1308, the quench detector compares the voltage difference to a voltage threshold to determine whether the voltage threshold condition has been violated or satisfied (or not). For example, a voltage threshold condition is violated or satisfied if the voltage difference is greater than or equal to a voltage threshold.

The various apparatus, methods, flow diagrams, and structure block diagrams described in this disclosure may be implemented in a computer processing system including program code comprising program instructions that are executable by the computer processing system. Other implementations may also be used. Further, the flow diagrams and structure block diagrams described in the present disclosure, which describe particular methods and/or corresponding acts in support of steps and corresponding functions in support of disclosed structural means, may also be utilized to implement corresponding software structures and algorithms, and equivalents thereof.

The various exemplary embodiments described in this disclosure can be implemented as one or more computer program products, i.e., one or more modules of computer program instructions encoded on a tangible program carrier for execution by, or to control the operation of, data processing apparatus. The computer readable medium can be a machine-readable storage device, a machine-readable storage substrate, a memory device, a composition of matter effecting a machine-readable propagated signal, or a combination of one or more of them.

A computer program (also referred to as a program, software, software application, script, or code) can be written in any form of programming language, including compiled or interpreted languages, or declarative or procedural languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data, in a single file dedicated to the program in question, or in multiple coordinated files, e.g., files that store one or more modules, sub programs, or portions of code. A computer program can be deployed to be executed on one computer or on multiple computers that are located at one site or distributed across multiple sites and interconnected by a communication network.

The processes and logic flows described in this disclosure can be performed by a processing system. For example, one or more programmable processors or digital signal processors (DSPs) can execute one or more computer programs to perform functions by operating on input data and generating output. The processes and logic flows can also be performed by special purpose logic circuitry, e.g., an FPGA (field programmable gate array) or an ASIC (application specific integrated circuit) or CPLD (Complex Programmable Logic Device), or a combination of various processors and special purpose logic circuitry.

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical, or optical disks. However, a computer need not have such devices.

To provide for interaction with a user, the disclosed embodiments can be implemented on a computer, e.g., a host computer 170 in FIG. 1, having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

The disclosed embodiments can be implemented in a computing system that includes a back end component, e.g., as a data server, or that includes a middleware component, e.g., an application server, or that includes a front-end component, e.g., a client computer having a graphical user interface or a Web browser through which a user can interact with an implementation of the subject matter described is this specification, or any combination of one or more such back-end, middleware, or front-end components. The components of the system can be interconnected by any form or medium of digital data communication, e.g., a communication network. The computing system can include clients and servers. A client and server are generally remote from each other and typically interact through a communication network. The relationship of client and server arises by virtue of computer programs running on the respective computers and having a client-server relationship to each other.

While this disclosure contains many exemplary implementations, they should not be construed as limitations on the scope of any invention or of what may be claimed, but rather as descriptions of features that may be specific to particular embodiments of particular inventions. Certain features that are described in this disclosure in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the disclosed embodiments should not be understood as requiring such separation in all embodiments, and it should be understood that the described program components and systems can generally be integrated together in a single software product or packaged into multiple software products.

1. A method of detecting quench in a superconducting device, the method comprising:
receiving real-time information of concurrently monitored electrical characteristics of a superconducting device in operation;
determining whether an electrical threshold is satisfied based on the received real-time information; and
detecting a quench condition if the electrical threshold remains satisfied over a predetermined period of time or a predetermined successive number of times.

2. The method according to claim 1, wherein the electrical threshold is a voltage threshold.

3. The method according to claim 2, wherein the determining operation comprises:
comparing a voltage difference to the voltage threshold in order to determine whether an electrical threshold is satisfied, the voltage difference being a difference between two voltage measurements obtained based on the monitored electrical characteristics at an instance in time.

4. The method according to claim 3, wherein the voltage measurements are of an inductive voltage or a resistive voltage.

5. The method according to claim 2, wherein the superconducting device comprises a superconducting coil having at least a first portion and a second portion, the method further comprising:
ascertaining a voltage across the first portion and a voltage across the second portion from the received real-time information, the determining operation comprising comparing a voltage difference between the voltage across the first portion and the voltage across the second portion to the voltage threshold in order to determine whether the voltage threshold is satisfied.

6. The method according to claim 2, wherein the superconducting device comprises a superconducting coil having a plurality of coil portions, the method further comprising:
ascertaining a voltage across each coil portion from the received real-time information, the determining operation comprising comparing a voltage difference between voltages across different coil portions to the voltage threshold in order to determine whether the voltage threshold is satisfied.

7. The method according to claim 2, wherein, during a current ramping phase for the superconducting device, the determining operation comprises:
ascertaining a voltage difference between (i) a voltage computed from a ramping current determined from the received real-time information and (ii) a voltage across the superconducting device determined from the received real-time information; and
comparing the voltage difference to the voltage threshold in order to determine whether the voltage threshold is satisfied.

8. The method according to claim 2, wherein the voltage threshold is less than or equal to 10 m-Volts.

9. The method according to claim 8, wherein the voltage threshold is between 0.5 and 5 m-Volts.

10. The method according to claim 1, further comprising:
controlling a termination of an operation of the superconducting device in response to a detection of a quench condition.

11. The method according to claim 10, wherein the controlling operation controls an energy extraction system to extract energy from the superconducting device and terminates power to the superconducting device from a power supply.

12. The method according to claim 10, wherein detection of a quench condition and interruption of a current to the superconducting device is implemented within about 1 m-sec to 5 m-sec from an occurrence of a quench in the device.

13. The method according to claim 1, further comprising:
monitoring a plurality of electrical characteristics of the superconducting device.

14. The method according to claim 1, further comprising:
extracting energy from the superconducting device and terminating power supplied to the superconducting device in response to a detection of a quench condition in the superconducting device.

15. The method according to claim 1, wherein the receiving, determining and detecting operations are implemented through a field programmable gate array (FPGA), application specific integrated circuit (ASIC), digital signal processor (DSP), complex programmable logic device (CPLD), or a combination thereof.

16. The method according to claim 1, further comprising selecting particular monitored electrical characteristics from a plurality of monitored electrical characteristics for which real-time information is received according to an operation phase of the superconducting device, the determining operation determining whether an electrical threshold is satisfied based on the received real-time information of the selected monitored electrical characteristics.

17. The method according to claim 1, wherein the superconducting device is a high temperature superconducting (HTS) device.

18. A device comprising:
a processing system for receiving real-time information of concurrently monitored electrical characteristics of a superconducting device in operation, determining whether an electrical threshold stored in memory is satisfied based on the received real-time information, and detecting a quench condition if the electrical threshold remains satisfied over a predetermined period of time or a predetermined successive number of times.

19. The device according to claim 18, wherein the electrical threshold is a voltage threshold.

20. The device according to claim 19, wherein the processing system compares a voltage difference to the voltage threshold in order to determine whether the electrical threshold is satisfied, the voltage difference being a difference between two voltage measurements obtained based on the monitored electrical characteristics at an instance in time.

21. The device according to claim 20, wherein the voltage measurement is of an inductive voltage or a resistive voltage.

22. The device according to claim 19, wherein the superconducting device comprises a superconducting coil having at least a first portion and a second portion, a voltage across the first portion and a voltage across the second portion being ascertainable from the received real-time information, the processing system being configured to compare a voltage difference between the voltage across the first portion and the voltage across the second portion to the voltage threshold in order to determine whether the voltage threshold is satisfied.

23. The device according to claim 19, wherein the superconducting device comprises an superconducting coil having a plurality of coil portions, a voltage across each coil portion being ascertainable from the received real-time information, the processing system being configured to compare a voltage difference between voltages across different coil portions to the voltage threshold in order to determine whether the voltage threshold is satisfied.

24. The device according to claim 19, wherein the processing system is configured to determine whether the voltage threshold is satisfied during a current ramping phase by:
determining a voltage difference between (i) a voltage computed from a ramping current determined from the received real-time information and (ii) a voltage across the superconducting device determined from the received real-time information; and
comparing the voltage difference to the voltage threshold in order to determine whether the voltage threshold is satisfied.

25. The device according to claim 19, wherein the voltage threshold is less than or equal to 10 m-Volts.

26. The device according to claim 25, wherein the voltage threshold is between 0.5 and 5 m-Volts.

27. The device according to claim 18, wherein the processing system is further configured to control a termination of an operation of the superconducting device in response to a detection of a quench condition.

28. The device according to claim 27, wherein the processing system is configured to detect a quench condition and control interruption of current to the superconducting device within 1 m-sec to 5 m-sec from an occurrence of a quench in the superconducting device.

29. The device according to claim 18, further comprising:
one or more sensors for monitoring a plurality of electrical characteristics of the superconducting device.

30. The device according to claim 18, further comprising:
an energy extraction system, coupled to the superconducting device, for extracting energy from the superconducting device in response to a quench detection.

31. The device according to claim 18, further comprising:
a power supply coupled to the superconducting device.

32. The device according to claim 18, wherein the processing system comprises a field programmable gate array (FPGA), application specific integrated circuit (ASIC), digital signal processor (DSP), complex programmable logic device (CPLD), or a combination thereof.

33. The device according to claim 18, wherein the processing system selects particular monitored electrical characteristics from a plurality of monitored electrical characteristics for which real-time information is received according to an operation phase of the superconducting device and determines whether an electrical threshold is satisfied based on the received real-time information of the selected monitored electrical characteristics.

34. The device according to claim 18, wherein the superconducting device is a high temperature superconducting (HTS) device.

35. The device according to claim 18, further comprising a memory for storing parameters that are used for detecting a quench condition.

36. A computer-implemented method of detecting quench in a high temperature superconducting (HTS) device, the method comprising:
receiving real-time information of concurrently monitored electrical characteristics of a high temperature superconducting (HTS) device in operation; and
discriminating between quench-related electrical signals and non-quench-related electrical signals observed from the received real-time information to determine a quench condition in the HTS device.

37. The method according to claim 36, further comprising:
obtaining a plurality of voltage measurements of the HTS device based on the received real-time information; and
detecting a presence of electrical signals in the HTS device from voltage subtraction of two voltage measurements from the plurality of voltage measurements,
wherein the discriminating operation comprises filtering non-quench-related electrical signals to determine a quench condition in the HTS device.

38. The method according to claim 37, wherein the filtering operation comprises:
counting a number of successive times the subtracted voltage is greater than or equal to a voltage threshold over time; and
determining a quench condition if the counted number of successive times is greater than or equal to a counter threshold.

39. A device comprising:
a processing system for receiving real-time information of concurrently monitored electrical characteristics of a high temperature superconducting (HTS) device in operation, and discriminating between quench-related electrical signals and non-quench-related electrical signals observed from the received real-time information to determine a quench condition in the HTS device.

40. The device according to claim 39, wherein the processing system further obtains a plurality of voltage measurements of the HTS device based on the received real-time information, and detects a presence of electrical signals in the HTS device from voltage subtraction of two voltage measurements from the plurality of voltage measurements, and filters non-quench-related signals to determine a quench condition in the HTS device.

41. The device according to claim 40, wherein the processing system counts a number of successive times the subtracted voltage is greater than or equal to a voltage threshold over time, and determines a quench condition if the counted number of successive times is greater than or equal to a counter threshold.

42. The device according to claim 39, further comprising a memory for storing parameters that are used for detecting a quench condition.

43. A computer-readable memory having stored thereon, executable instructions that, if executed by a computing device, cause the computing device to perform a method comprising:
receiving real-time information of concurrently monitored electrical characteristics of a superconducting device in operation;
determining whether an electrical threshold is satisfied based on the received real-time information; and
detecting a quench condition if the electrical threshold remains satisfied over a predetermined period of time or a predetermined successive number of times.

44. The computer-readable memory according to claim 43, wherein the superconducting device is a high temperature superconducting (HTS) device.

45. A computer-readable memory having stored thereon, executable instructions that, if executed by a computing device, cause the computing device to perform a method comprising:
receiving real-time information of concurrently monitored electrical characteristics of a high temperature superconducting (HTS) device in operation; and
discriminating between quench-related electrical signals and non-quench-related electrical signals observed from the received real-time information to determine a quench condition in the HTS device.

46. The method according to claim 17, further comprising: transmitting a signal to cause termination of the operation of the HTS device in response to a detection of a quench condition.

47. A computer-implemented method of detecting quench in a high temperature superconducting (HTS) device, the method comprising:
receiving real-time information of concurrently monitored electrical characteristics of a high temperature superconducting (HTS) device during operation;
determining whether an electrical threshold is satisfied based on the received real-time information;
detecting a quench condition if the electrical threshold remains satisfied over a predetermined period of time or a predetermined successive number of times; and
transmitting a signal to cause termination of the operation of the HTS device in response to a detection of a quench condition.
